(19) United States
(12) Patent Application Publication
(10) Pub. No.: US 2008/0012067 A1
(43) Pub. Date: Jan. 17, 2008

(54) Transistor and memory cell array and methods of making the same

(76) Inventor: Dongping Wu, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/486,385

(22) Filed: Jul. 14, 2006

(51) Int. Cl. H01L 29/76; H01L 21/336

(52) U.S. Cl. 257/330; 438/270; 438/589; 257/334

(57) ABSTRACT

A method of forming a transistor involves defining an active area by defining isolation trenches, the isolation trenches being adjacent to the active area, and forming a gate electrode after defining the isolation trenches. The gate electrode is formed by etching a gate groove in the active area selectively with respect to an insulating material filling the isolation trenches, etching the insulating material filling the isolation trenches at a portion adjacent to a channel such that a portion of the channel having the shape of a ridge with a top side and two lateral sides is uncovered, providing a gate insulating material on the top side and the lateral sides, and providing a conducting material on the gate insulating layer such that the gate electrode is disposed along the top side and the two lateral sides of the channel.

The invention relates to a transistor and a memory cell array, and methods of forming a transistor, which can for example be used in a dynamic random access memory cell of a memory cell array.

### BACKGROUND

Memory cells of a dynamic random access memory (DRAM) generally comprise a storage capacitor for storing an electrical charge which represents information to be stored, and an access transistor, which is connected with the storage capacitor. The access transistor comprises first and second source/drain regions, a channel connecting the first and the second source/drain regions as well as a gate electrode controlling an electrical current flowing between the first and second source/drain regions. The transistor usually is at least partially formed in the semiconductor substrate. The gate electrode forms part of a wordline and is electrically isolated from the channel by a gate dielectric. By addressing the access transistor via the corresponding wordline the information stored in the storage capacitor is read out.

By way of example, the storage capacitor can be implemented as a trench capacitor in which the two capacitor electrodes are disposed in a trench which extends in the substrate in a direction perpendicular to the substrate surface. According to another implementation of the DRAM memory cell, the electrical charge is stored in a stacked capacitor, which is formed above the surface of the substrate.

A memory device further comprises a peripheral portion. Generally, the peripheral portion of the memory device includes circuitry for addressing the memory cells and for sensing and processing the signals received from the individual memory cells. Usually, the peripheral portion is formed in the same semiconductor substrate as the individual memory cells.

In the transistors of a memory cell, there is a lower boundary of the channel length of the transistor, below which the isolation properties of the access transistor in a non-addressed state are not sufficient. The lower boundary of the effective channel length L_{EFF} limits the scalability of planar transistors cells having an access transistor which is horizontally formed with respect to the substrate surface of the semiconductor substrate.

A recessed channel transistor employs an arrangement in which the effective channel length L_{EFF} is enhanced. In such a transistor, the gate electrode is arranged in a groove which is formed in the semiconductor substrate. Another known transistor concept is used in the FinFET. The active area of a FinFET usually has the shape of a fin or a ridge which is formed in a semiconductor substrate between the two source/drain regions.

### SUMMARY

In one embodiment of the present invention, a method of manufacturing a transistor comprises defining the memory cell array to include a plurality of memory cells, each memory cell comprising a storage capacitor and a transistor, defining isolation trenches being adjacent to an active area, and forming a gate electrode during formation of the transistor after defining the isolation trenches, comprising etching a gate groove in the active area selectively with respect to an insulating material filling the isolation trenches, the gate groove having an upper sidewall portion, a lower sidewall portion and a bottom portion, the lower sidewall portion being adjacent to the bottom portion of the gate groove, the upper sidewall portion being disposed above the lower sidewall portion, etching the insulating material filling the isolation trenches at a portion adjacent to a channel such that a portion of the channel is uncovered, the uncovered portion having the shape of a ridge comprising a top side and two lateral sides, providing a gate insulating material on the top side and the lateral sides, providing a conducting material on the gate insulating layer configured such that the gate electrode is disposed along the top side and the two lateral sides of the channel, wherein etching the insulating material in the isolation trenches comprises covering the upper sidewall portion of the gate groove with a cover layer, so that a lower sidewall portion adjacent to the isolation trenches is left uncovered, and selectively etching the insulating material with respect to the material of the cover layer.

Moreover, a method of forming a memory cell array comprises providing a semiconductor substrate having a surface, providing a plurality of isolation trenches in the semiconductor substrate, the isolation trenches extending in a first direction, thereby defining a plurality of active areas, each of the active areas being delimited by two isolation trenches along a second direction perpendicular to the first direction, providing an insulating material in each of the isolation trenches, providing a transistor in the active areas, by providing a first and a second source/drain regions, forming a channel which is disposed between the first and second source/drain regions, and providing a gate electrode for controlling an electrical current flow between the first and second source/drain regions, providing a plurality of storage capacitors, wherein providing a gate electrode comprises etching a gate groove in an active area selectively with respect to the insulating material filling the isolation trenches, the gate groove having a sidewall and a bottom portion, etching the insulating material in the isolation trenches at a portion adjacent to the channel so that a portion of the channel is uncovered, the portion having the shape of a ridge comprising a top side and two lateral sides, providing a gate insulating layer on the top side and the two lateral sides, and providing a conducting material on the gate insulating layer so that as a result the gate electrode is disposed along the top side and the two lateral sides of the channel, wherein etching the insulating material in the isolation trenches comprises covering the upper sidewall portion of the gate groove with a cover layer, so that a lower sidewall portion adjacent to the isolation trenches is left uncovered, and selectively etching the insulating material with respect to the material of the cover layer.

In addition, a method of forming a transistor comprises defining an active area by defining isolation trenches, the isolation trenches being adjacent to the active area, and forming a gate electrode after defining the isolation trenches, comprising etching a gate groove in the active area selectively with respect to an insulating material filling the isolation trenches, the gate groove having an upper sidewall portion, a lower sidewall portion and a bottom portion, the lower sidewall portion being adjacent to the bottom portion of the gate groove, the upper sidewall portion being disposed above the lower sidewall portion, etching the insulating material filling the isolation trenches at a portion adjacent to a channel such that a portion of the channel is uncovered, the uncovered portion having the shape of a ridge comprising a top side and two lateral sides, providing a gate insulating material on the top side and the lateral sides, providing a conducting material on the gate insulating layer configured such that the gate electrode is disposed along the top side and the two lateral sides of the channel, wherein etching the insulating material in the isolation trenches comprises covering the upper sidewall portion of the gate groove with a cover layer, so that a lower sidewall portion adjacent to the isolation trenches is left uncovered, and selectively etching the insulating material with respect to the material of the cover layer.

Moreover, a transistor, being at least partially formed in a semiconductor substrate, comprises a first and a second source/drain region, a channel being formed between the first and the second source/drain regions, and a gate electrode for controlling a conductivity of the channel, the gate electrode being disposed in a gate groove which is defined in the semiconductor substrate, wherein the channel has the shape of a ridge including a top side and two lateral sides and the gate electrode is adjacent to the top side and the two lateral sides, wherein the gate electrode comprises an upper portion and a lower portion, the lower portion of the gate electrode being adjacent to the top side of the channel, the upper portion being disposed above the lower portion and wherein the width of the gate electrode in the upper portion is smaller than the width of the gate electrode in the lower portion in a cross-section which is perpendicular to a line connecting first and second source/drain regions.

In addition, a memory cell comprises means for storing a charge, and a transistor for accessing the means for storing the charge, the transistor being at least partially formed in a semiconductor substrate having a surface, the transistor comprising a first and a second source/drain region, a channel being formed between the first and the second source/drain regions, and a gate electrode for controlling a conductivity of the channel, the gate electrode being disposed in a gate groove which is defined in the semiconductor substrate, wherein the channel has the shape of a ridge including a top side and two lateral sides and the gate electrode is adjacent to the top side and the two lateral sides, wherein the gate electrode comprises an upper portion and a lower portion enclosing the ridge at three sides thereof, wherein the gate electrode comprises means for reducing the width of the gate electrode in the lower portion with respect to the upper portion in a cross-section which is perpendicular to a line connecting first and second source/drain regions.

The above and still further objects, features and advantages of the present invention will become apparent upon consideration of the following detailed description of specific embodiments thereof, wherein identical numerals define identical components in the drawings.

### BRIEF DESCRIPTION OF THE DRAWINGS

FIG. 1A shows a cross-sectional view of the transistor according to an embodiment of the present invention.

FIG. 1B shows another cross-sectional view of the transistor shown in FIG. 1A.

FIG. 2A shows a cross-sectional view of a substrate when starting the method according to an embodiment of the present invention.

FIG. 2B shows another cross-sectional view of the substrate when starting the method according to an embodiment of the present invention.

FIG. 2C shows a plan view of a substrate when starting the method according to an embodiment of the present invention.

FIG. 3A shows a cross-sectional view of the substrate after performing a processing step.

FIG. 3B shows another cross-sectional view of the substrate after performing the processing step.

FIG. 3C shows a plan view of the substrate after performing the processing step.

FIG. 4A shows an exemplary plan view on a substrate surface.

FIG. 4B shows a further exemplary plan view of the substrate surface.

FIG. 4C shows still a further exemplary plan view of the substrate surface.

FIG. 5A shows a cross-sectional view of the substrate after performing a further processing step.

FIG. 5B shows another cross-sectional view of the substrate after performing the processing step.

FIG. 6A shows a cross-sectional view of the substrate after performing a further etching step.

FIG. 6B shows another cross-sectional view of the substrate after performing the etching step.

FIG. 7A shows a cross-sectional view of the substrate after depositing a sidewall spacer.

FIG. 7B shows another cross-sectional view of the substrate after depositing the sidewall spacer.

FIG. 7C shows a plan view of the substrate after depositing the sidewall spacer.

FIG. 8A shows a cross-sectional view of the substrate after performing a further etching step.

FIG. 8B shows another cross-sectional view of the substrate after performing the etching step.

FIG. 8C shows a plan view of the substrate after performing the etching step.

FIG. 9A shows a cross-sectional view of the substrate after performing still a further etching step.

FIG. 9B shows another cross-sectional view of the substrate after performing the etching step.

FIG. 10A shows a cross-sectional view of the substrate after forming a gate insulating layer.

FIG. 10B shows a cross-sectional view of the substrate after forming the gate insulating layer.

FIG. 10C shows a plan view of the substrate after forming the gate insulating layer.

FIG. 11A shows a cross-sectional view of the substrate after depositing a polysilicon layer.

FIG. 11B shows another cross-sectional view of the substrate after depositing the polysilicon layer.

FIG. 12 shows a cross-sectional view of the substrate after performing an optional processing step.

FIG. 13A shows a cross-sectional view of the substrate after depositing another polysilicon layer.

FIG. 13B shows another cross-sectional view of the substrate after depositing the polysilicon layer.

FIG. 14 shows an exemplary view of the completed memory cell.

FIG. 15 shows an exemplary plan view of a completed memory device.

### DETAILED DESCRIPTION

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

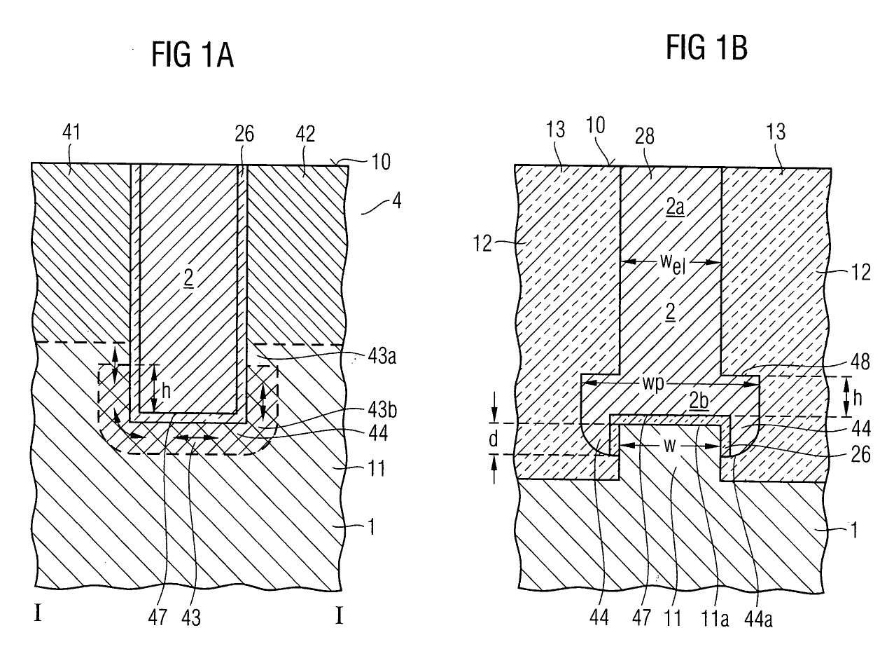

FIG. 1A illustrates a cross-sectional view of an exemplary transistor 4 along a first direction which is parallel to a line connecting the first and the second source/drain regions 41, 42.

The transistor 4 comprises first and second source/drain regions 41, 42 and a channel 43 connecting the first and second source/drain regions 41, 42. The conductivity of the channel is controlled by the gate electrode 2. As is indicated by broken lines, in the plane of the drawing which is taken before or behind the illustrated cross-sectional view, respectively plate-like portions 44 of the gate electrode 2 are disposed so as to enclose the channel 43. Accordingly, the gate electrode 2 is adjacent to three sides of the lower portion 43b of the channel. To be more specific, as is shown in FIG. 1A, starting a path from the first source/drain region 41, there is an upper channel portion 43a in which the gate electrode 2 is adjacent only to one side of the channel. Thereafter, the lower portion of the channel 43b follows. In the lower portion 43b, the channel region is enclosed at three sides thereof by the gate electrode. In this portion, the plate-like portions of the gate electrode 44 are adjacent to the channel region. Thereafter, again the upper portion of the channel 43a follows, in which only one side of the channel is adjacent to the gate electrode 2.

In FIG. 1A the first and second source/drain regions 41, 42 are adjacent to the substrate surface 10. Moreover, the gate electrode 2 is insulated from the first and second source/drain regions 41, 42 by a gate insulating layer 26. The plate-like portions 44 are disposed so as to extend to a height h which is measured from the bottom side 47 of the gate electrode 2 to the upper side 48 of the plate-like portions.

Usually, the first source/drain region 41 is connected with a storage capacitor (not shown in this drawing) and the second source/drain region 42 is connected with the bitline (not shown in this drawing).

The gate electrode 2 usually is made from polysilicon. The first and second source/drain regions 41, 42 are implemented as normally or heavily doped silicon regions and, consequently, exhibit an excellent electrical conductivity. Optionally, the first source/drain region 41 or both source/drain regions 41, 42 may additionally comprise a lightly doped region (not shown) or a heavily doped region, which is disposed between the channel region and the heavily doped regions, respectively. The channel 43 is lightly p-doped and therefore insulates the first from the second source/drain regions unless a suitable voltage is applied to the gate electrode 2.

FIG. 1B shows a cross-sectional view of the transistor structure shown in FIG. 1A. The cross-sectional view shown in FIG. 1B is taken perpendicularly with respect to the cross-sectional view shown in FIG. 1A. Accordingly, the first and second source/drain regions 41, 42 are disposed before and behind the plane of the drawing shown in FIG. 1B, respectively. In FIG. 1B, isolation trenches 12 for defining an active area 11 are shown. As can be seen from FIGS. 1A and 1B, the gate electrode 2 is formed in a gate groove which extends in the substrate surface 10. The gate electrode 2 is adjacent to each of the isolation trenches 12. The gate electrode 2 is insulated from the active area 11 by the gate insulating layer 26. As can be seen, in the upper portion, the gate electrode 2 is delimited by each of the isolation trenches 12. In the lower portion of the gate electrode, pockets are formed so as to extend in the isolation trenches 12, the pockets being filled with the gate conductive material so as to form the plate-like portions 44. In the cross-sectional view shown in FIG. 1B, the active area 11 has width w and the gate electrode extends to a depth d which is measured from the top side 11a of the active area 11 to the bottom side 44a of each of the plate-like portions 44.

As can be seen from FIG. 1B, the gate electrode comprises an upper portion 2a and a lower portion 2b comprising two plate-like portions 44. The width wₚ of the lower portion 2b comprising the plate-like portions 44 is larger than the width Wₑ₁ of the gate electrode in the upper portion 2a thereof. In particular, the width Wₑ₁ of the gate electrode 2 refers to the width of the gate electrode 2 in a portion in which the width of the gate electrode is determined by the distance between adjacent isolation trenches 12. Moreover, the width Wₚ of the plate-like portions refers to a portion of the gate electrode in which the gate electrode is disposed beneath the first and second source/drain regions 41, 42. For example, in a cross-section which is taken perpendicularly to the direction of a line connecting first and second source/drain regions the maximum of the width Wₚ of the bottom portion 2b of the gate electrode comprising the plate-like portions 44 is larger than the maximum of the width Wₑ₁ of the upper portion 2a of the gate electrode.

By way of example, the depth of the gate groove may be less than 500 nm, for example, 150 to 350 nm, measured from the substrate surface to the bottom side 47 of the gate groove. The width Wₑ₁ of the upper portion of the gate groove may, for example, be less than 120 nm, for example, 20 to 100 nm. Moreover, by way of example, the difference between the width Wₚ of the bottom portion and the width Wₑ₁ of the upper portion of the gate groove may be 10 to 40 nm, for example, 20 to 30 nm.

For manufacturing a transistor shown in FIG. 1, first, a semiconductor substrate, for example, a silicon substrate, which may be for example lightly p-doped is provided. For example, at least part of the components of a storage capacitor may already be completed. For example, the relevant components of a trench capacitor which is at least partially formed in the semiconductor substrate may be completed. Alternatively, the relevant components of a stacked capacitor, which is at least partially formed above the semiconductor substrate surface, may be completed. Moreover, by way of example, a blanket ion implantation step may be performed in order to provide a doped portion forming the source/drain regions. Nevertheless, for the sake of convenience, the illustration of the doped portion will be omitted from the following drawings.

Thereafter, first, a silicon dioxide layer (not shown) is deposited on the surface 10 of a semiconductor substrate, followed by a silicon nitride layer 14 having a thickness of approximately 200 to 500 nm, for example 300 to 400 nm. Thereafter, isolation trenches are defined in a manner as is conventional. For example, the isolation trenches may be defined photolithographically so as to expose predetermined substrate surface portions 10, followed by an etching step for etching the silicon material in the exposed portions. By way of example, the isolation trenches may have a depth of 300 nm or more, when measured from the substrate surface 10. For example, the depth of the isolation trenches should be larger than the depth of the gate grooves to be formed. Thereafter, the isolation trenches are filled with an insulating material. For example, the isolation trenches may be filled with various dielectrics. By way of example, the isolation trenches 12 are filled with silicon dioxide 13. In the lower part of the isolation trenches an additional Si₃N₄-layer may be provided so as to act as an etch stop during the subsequent etching steps of etching the insulating material of the isolation trenches.

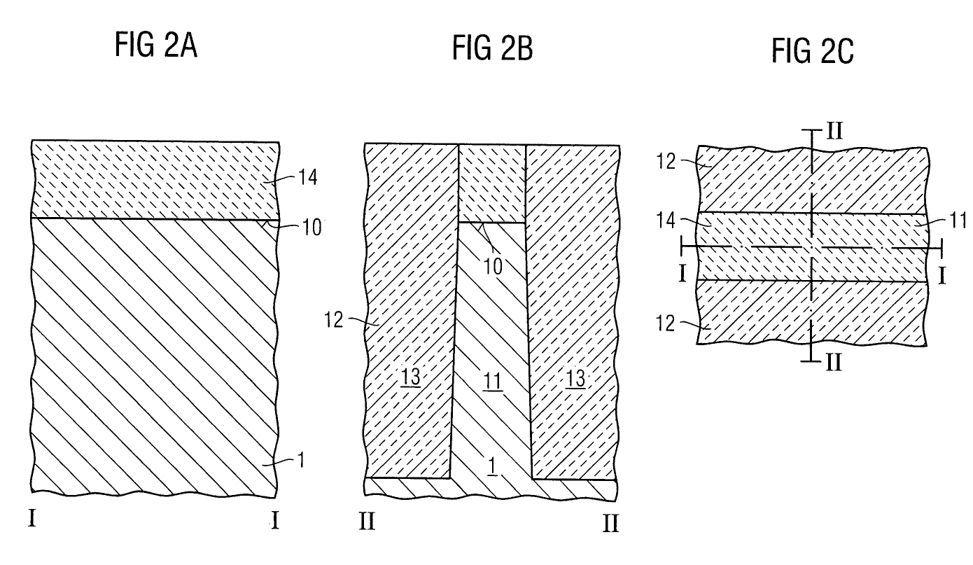

FIG. 2A shows a cross-sectional view of the resulting structure between I and I as can be taken from FIG. 2C. As can be seen, on the surface 10 of a semiconductor substrate 1, a silicon nitride layer 14 is disposed. Moreover, FIG. 2B shows a cross-sectional view of the resulting structure between II and II as can be taken from FIG. 2C. As can be seen, an active area portion 111 is laterally confined by isolation trenches 13 which are filled with an insulating material 12. On top of the active area portion 11, a silicon nitride portion 14 is provided. As can be seen, the isolation trenches do not have completely rectangular sidewalls. To be more specific, the isolation trenches are slightly tapered. As a result, the width of the active areas 11 is larger in a bottom portion than in a top portion thereof. Moreover FIG. 2C shows a plan view. As can be seen, the isolation trenches 13 are formed as lines. In the spaces between adjacent lines, lines of silicon nitride material 14 are provided.

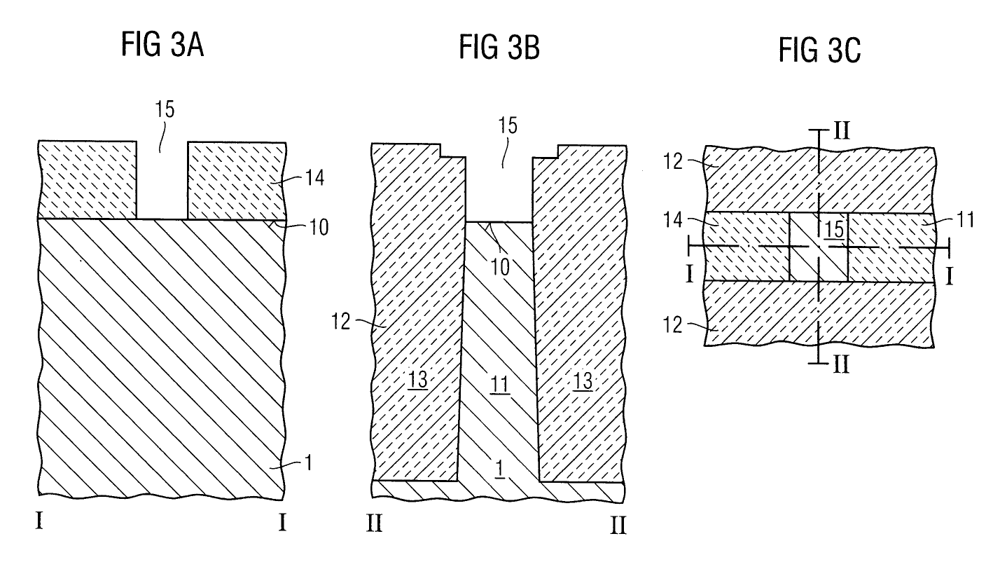

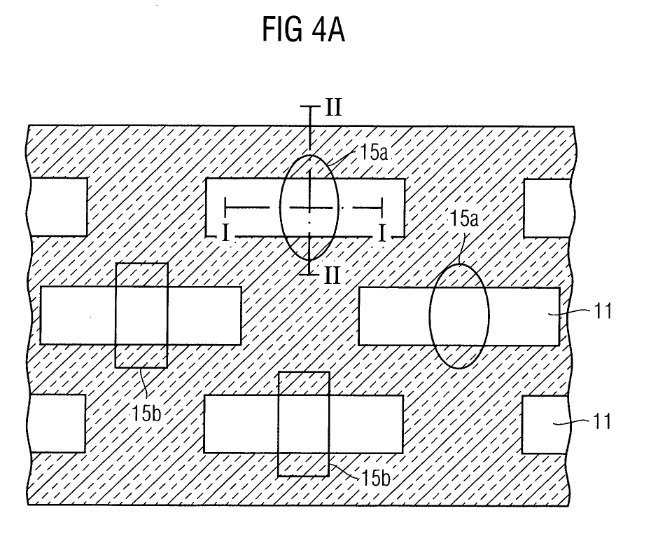

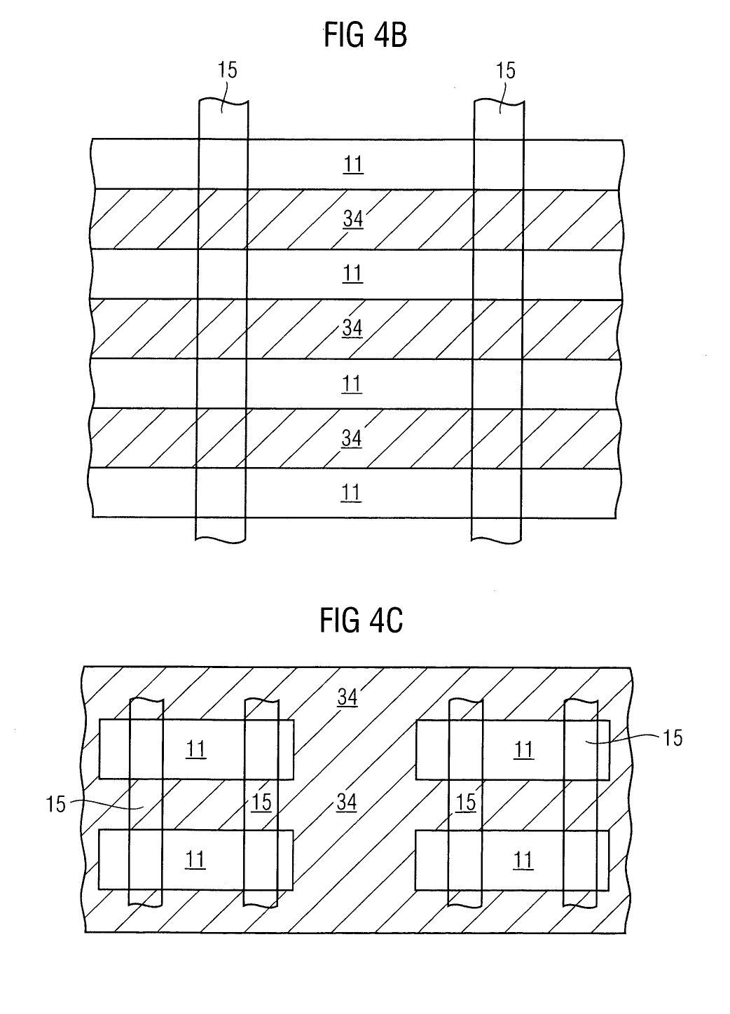

In the next step, groove openings are defined. In particular, a photoresist material is applied and is patterned using a recess channel mask. As will be explained with reference to FIGS. 4A to 4C, the recess channel mask may have various shapes. In particular, the recess channel mask is designed in such a manner, that a dot-like portion of the silicon nitride layer 14 is etched to as to form a groove opening 15. FIG. 3A shows a cross-sectional view of the substrate between I and I after etching the groove opening in the silicon nitride layer 14. In particular, this etching step of etching silicon nitride has a high selectively to silicon dioxide. In this respect, the term “selective etching step” refers to an etching step in which a first material is etched at a much higher etching rate compared to the material of another layer. For example, the ratio of the etching rates of the first material to the other material may be 4:1 or more. For example, in the etching step shown in FIG. 3A, the etching rate of silicon nitride is four times the etching rate of silicon dioxide so as to ensure the required selectivity. As can further be seen from FIG. 3B, showing a cross-sectional view between II and II, the silicon nitride layer 14 is completely removed from the spaces between adjacent isolation trenches.

FIG. 3C shows a plan view of the resulting structure. As can be seen, groove openings 15 are formed so as to expose predetermined substrate portions 1. Stripes of remaining silicon nitride material 14 are disposed between adjacent groove openings 15.

FIGS. 4A to 4C show various plan views of the semiconductor substrate showing exemplary shapes of the recess channel mask. For example, as is shown in FIG. 4A, the active areas may be arranged in a staggered manner so as to form a checkerboard pattern. In this case, the groove openings 15 may be circular or oval openings 15a or they may be openings 15b having the shape of segments of lines.

Nevertheless, it lies within the scope of the present invention that the active areas may as well be arranged in lines, as is shown in FIG. 4B. In this case, the groove openings 15 may be lines, as is shown in FIG. 4B. Likewise the active areas 11 may as well be arranged in a regular grid. In this case, the active areas 11 are arranged in rows and columns. In this case, the mask opening 15 may as well have the shape of lines or segments of lines, as is shown in FIG. 4C, for example.

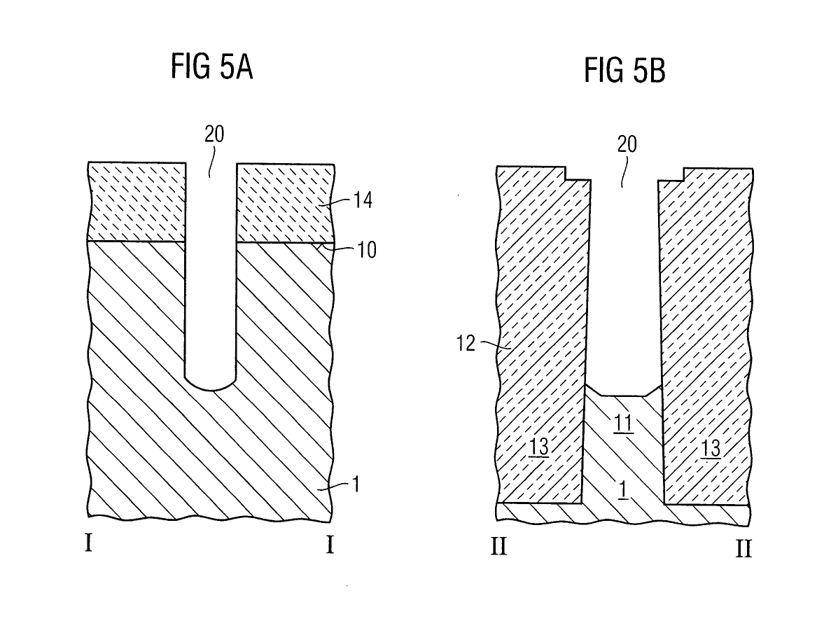

In the next step, an etching step of etching the silicon substrate material 1 selectively with respect to the material of the isolation trenches 12 and the silicon nitride layer 14 is performed. For example this may be a dry etching step. As a result, the silicon nitride layer as well as the material filled in the isolation trenches 12 may be slightly recessed. In addition, gate grooves 20 are etched in the uncovered substrate portions. In particular, the gate grooves 20 are etched self-aligned with respect to the active areas 11. FIG. 5A shows a cross-sectional view of the substrate after this etching step between I and I. As can be seen, a gate groove 20 is formed in the substrate surface 10. For example, the gate groove 20 may extend to a depth of approximately 100 to 500 nm, measured from the substrate surface 10.

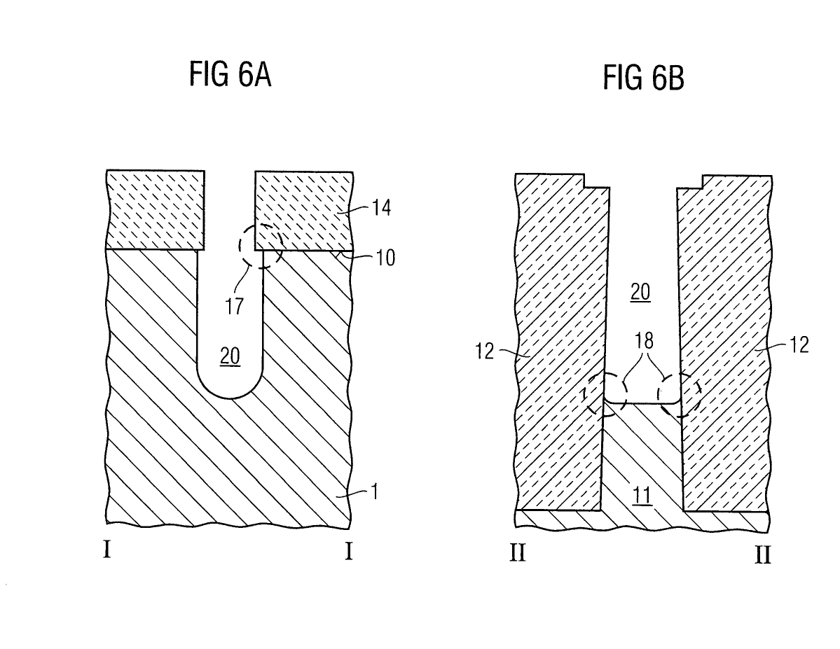

Moreover, FIG. 5B shows a cross-sectional view between II and II which is taken after this etching step. As can be seen, the gate groove 20 extends in the active area 11. Due to the fact, that the width of the active area 11 is smaller in the upper portion of the drawings than in the bottom portion of the drawings, substrate portions remain at the edges of the active area 11. Moreover, part of the insulating material of the isolation trenches 12 is recessed in the upper portion. Optionally, this etching step may be followed by an isotropic silicone etching step so that, as a result, the gate groove 20 is flattened in the cross-sectional view shown between II and II. The resulting structure after this optional processing step is shown in FIG. 6. As is shown in FIG. 6A, an upper portion of the substrate is recessed so as to form the recessed portion 17 in a cross-sectional view between I and I. Moreover, as can be seen from FIG. 6B, between II and II, a groove flattening portion 18 is produced.

Thereafter, the upper sidewall portion of the gate groove is covered with a cover layer so that a lower sidewall portion adjacent to the isolation trenches is left uncovered.

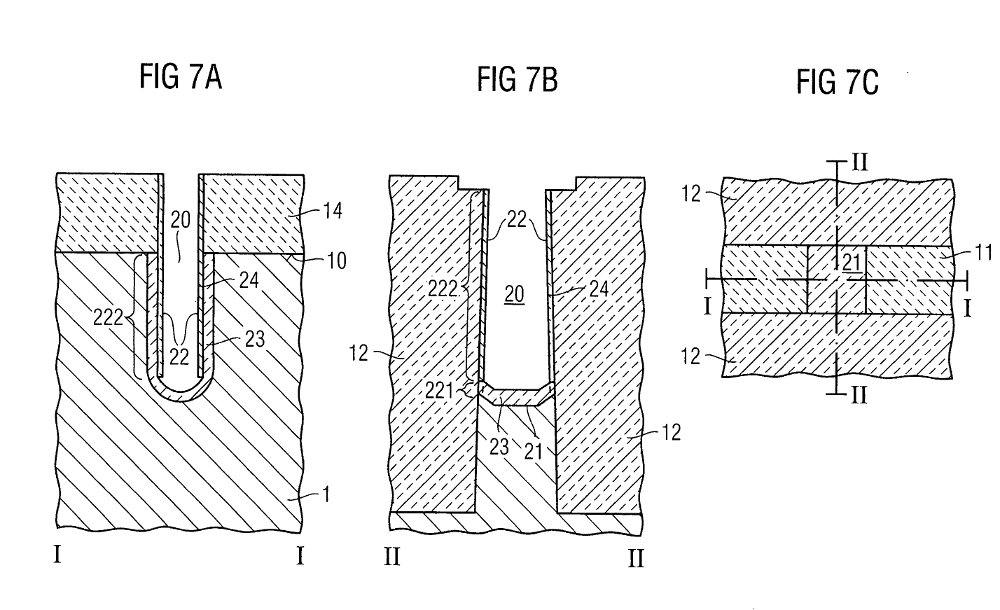

Optionally, this may be accomplished by forming a sacrificial liner on the sidewalls and the bottom portion of the gate groove 20. In particular, a silicon dioxide liner 23 may be formed. For example, the silicon dioxide liner 23 can be thermally grown or may be formed by an oxide deposition step. By way of example, also a combination of thermally growing a silicon dioxide layer and depositing an oxide layer may be used. For example, the silicon dioxide liner 23 may have a thickness of 5 to 20 nm. In particular, by selecting the thickness of the silicon dioxide liner, the vertical extension of the lower sidewall portion may be adjusted. Moreover, due to this liner, the final thickness of the inner spacer of the completed gate electrode is increased. Thereafter, optionally, an anisotropic etching step may be performed so that the silicon dioxide liner 23 may be removed from the horizontal portions of the gate groove 20. Thereafter, a cover layer 24 is deposited on the sidewalls of the gate grooves. To be more specific, a cover layer 24, for example, a silicon nitride layer may be conformally deposited, followed by an anisotropic etching step. As a result, the cover layer 24 remains only on the vertical sidewalls of the gate groove 20. As can be seen in FIG. 7A, showing a cross-sectional view between I and I, now the sidewalls 22 of the gate grooves 20 are covered with the silicon dioxide liner 23. The silicon dioxide liner on the sidewalls is covered with a silicon nitride liner 24. For example, the silicon nitride liner 24 may be as thin as possible. By way of example, the thickness of the silicon nitride liner may be 3 to 10 nm. The sum of the thicknesses of the cover layer 24 and the sacrificial liner 23 should be less than half of the width of the gate groove. Moreover, the bottom portion of the gate groove 20 is covered with the silicon dioxide liner 23. Moreover, FIG. 7B shows a cross-sectional view between II and II of the resulting structure. As can be seen, the top sidewall portion 222 is covered with the silicon nitride liner 24. Moreover, the bottom portion of the gate groove 21 is covered with the silicon dioxide liner 23. Moreover, in the lower sidewall portion 221 also a portion of the silicon dioxide liner 23 is provided. To be more specific, there is a special processing sequence of first forming the sacrificial layer 23 followed by depositing and anisotropically etching the cover layer 24. As a result, the lower portion 221 of the sidewall is covered with the sacrificial layer, whereas the upper portion of the sidewall 222 is covered with the cover layer 24. FIG. 7C shows a plan view of the resulting structure.

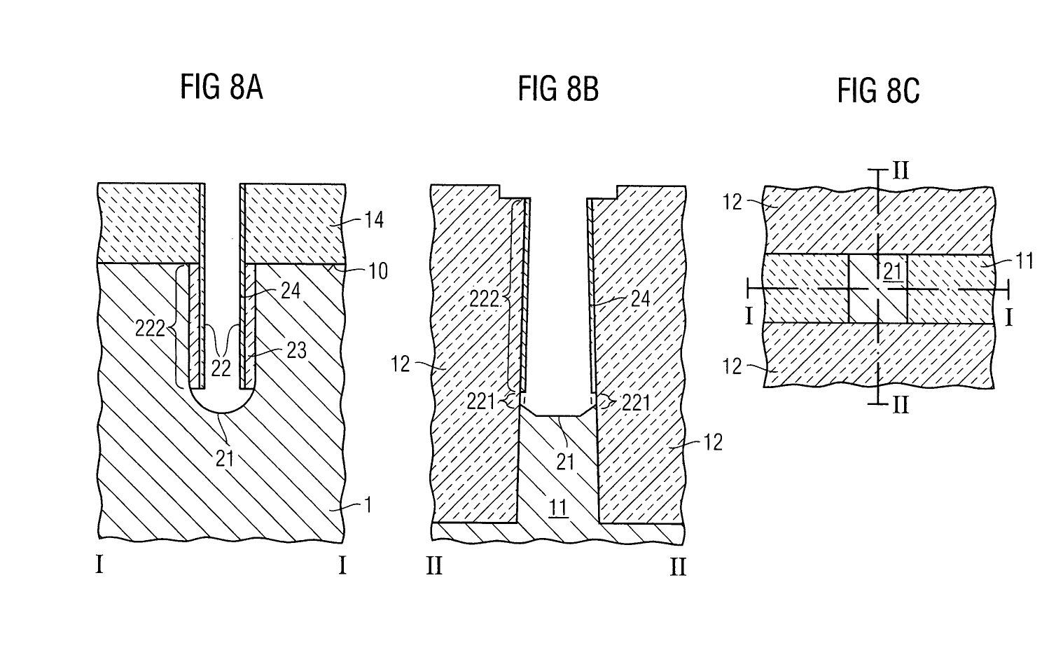

In the next step, an etching step of etching the sacrificial layer, for example, the silicon dioxide layer 23 is performed. By way of example, this etching step may be a dry etching step or it may be a wet etching step which is selective with respect to silicon nitride and to silicon. As a result, the structure shown in FIG. 8A to 8C is obtained. As can be seen from FIG. 8A showing a cross-sectional view between I and I, the silicon dioxide layer 23 is removed from the bottom portion 21 of the gate groove. Moreover, the upper portion 222 of the sidewalls is covered with the silicon dioxide layer 23, the silicon nitride liner 24 being disposed on the silicon dioxide layer 23. As can be seen from the cross-sectional view between II and II which is shown in FIG. 8B, the bottom portion 21 of the gate groove is uncovered. Moreover, the lower sidewall portion 221 of the gate groove 20 is as well uncovered. In addition, the upper sidewall portion 222 of the gate groove is covered with a silicon nitride liner 24. FIG. 8C shows a plan view of the resulting structure.

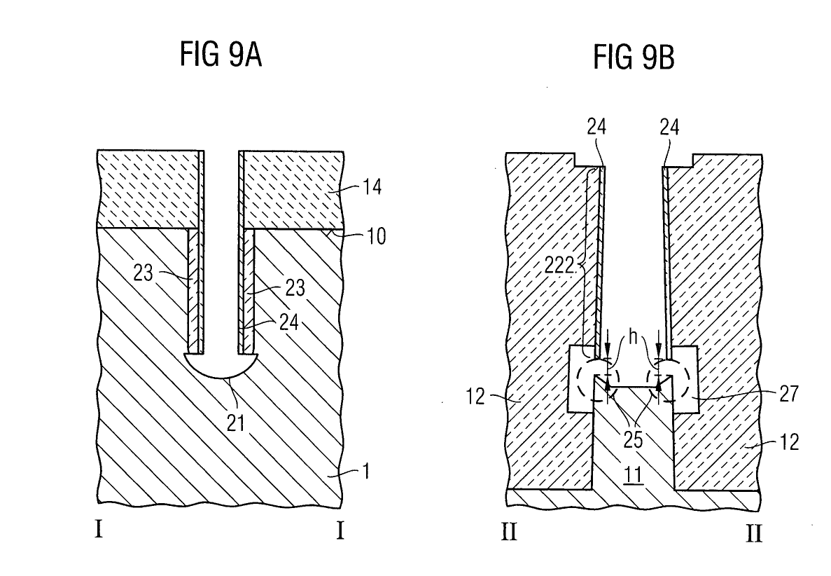

Thereafter, optionally an etching step of etching silicon substrate material may be performed. In particular, this etching step is selective with respect to silicon nitride and the insulating material 13 filling the isolation trenches 12. For example, this etching step may comprise an isotropic etching step so that the silicon tips 25 may be removed. In this case, as a result, the active area 11 has a rounded shape in the upper portion thereof. In particular, as is shown in FIG. 9B, by this etching step the value of h is determined, thus setting the height of the conductive material in a portion between the plate-like portions and the groove portion of the gate electrode to be formed. Moreover, the depth of the gate groove 20 is determined by the sum of the depth of the etching steps of etching silicon substrate material.

As a further alternative, the upper sidewall portion of the gate groove may be covered with a cover layer by providing a cover layer 24 on the vertical sidewall portions of the gate groove. By way of example, this may be accomplished by conformally depositing the cover layer 24 and performing an anisotropic etching step so as to remove the horizontal portions of this layer. Thereafter, an etching step of etching silicon substrate material so that a lower sidewall portion of the gate groove adjacent to the isolation trenches is left uncovered. Nevertheless, as is clearly to be understood, the upper sidewall portion of the gate groove may be covered with a cover layer by any other method. For example, a suitable deposition method or a back-etching method may be employed.

Thereafter, an etching step of etching the material 13 of the isolation trenches 12 is performed. For example, if the isolation trenches 12 are filled with silicon dioxide, this may be accomplished by a wet etching step using HF containing solvents or HF. In particular, this etching step is selective with respect to silicon nitride and silicon. Moreover, this etching step may as well be accomplished by an isotropic dry etching step, in which the silicon dioxide material is etched selectively with respect to silicon nitride and silicon. As a further alternative, wet and dry etching steps may be combined.

Optionally, an annealing step in a hydrogen (H₂) atmosphere may be performed at a high temperature so as to further round the Si tip or horn 25. For example, this annealing step may be performed at a temperature of less than 1000° C., for example, approximately 700° C. for typically 1 minute or more or less depending from the tip shape to be achieved. Optionally, this annealing step may be performed before or after the step of etching the insulating material 13 of the isolation trenches 12. The resulting structure is shown in FIGS. 9A and 9B. As can be seen from FIG. 9A showing a cross-sectional view between I and I, the bottom portion 21 of the gate grooves is slightly enlarged. Moreover, as can be seen from FIG. 9B, showing a cross-sectional view between II and II, pockets 27 are defined in the isolation trenches 12.

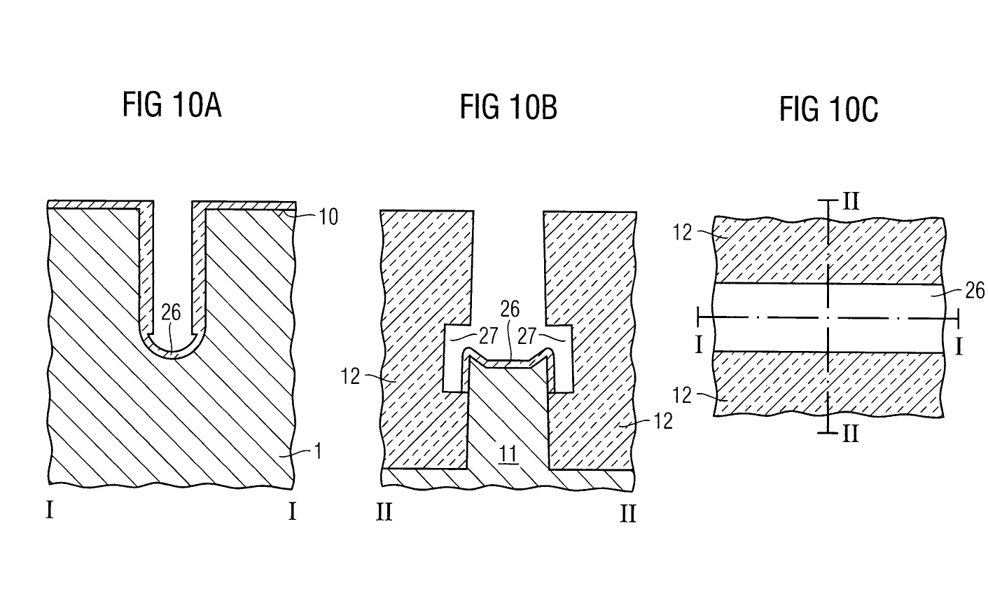

In the next step, the silicon nitride layers 14, 24 are removed, for example, by a suitable wet etching step. In particular, this etching step is selective with respect to silicon dioxide and silicon. Thereafter, a gate insulating layer 26 is provided. For example, the gate insulating layer 26 may be provided by performing a thermal oxidation step. For example, this gate insulating layer may as well serve as a gate insulating layer in the non-memory cell portion. Moreover, different types or thicknesses of gate oxides may be formed for different support devices. FIGS. 10A to 10C show a resulting structure. As can be seen from FIG. 10A, showing a cross-sectional view between I and I, a gate insulating layer 26 is provided.

For example, the remaining portions of the sacrificial liner 23 covering the upper portions of the sidewalls of the gate groove, may act as an inner spacer for insulating the gate electrode from the source/drain portions. Accordingly, the thickness of the gate insulating layer 26 may be smaller in the bottom portion of the gate groove than on the sidewall portions. If the sacrificial liner 23 has been thermally grown, the quality of this inner spacer is improved with respect to a conventional spacer. As can be seen from FIG. 10B, showing a cross-sectional view between II and II, pockets 27 are formed which are adjacent to the gate groove 20. In this cross-sectional view the active area 11 is covered with the silicon dioxide layer 26. In the plan view shown in FIG. 10C the entire substrate surface is covered with a silicon dioxide layer 26, 12, respectively.

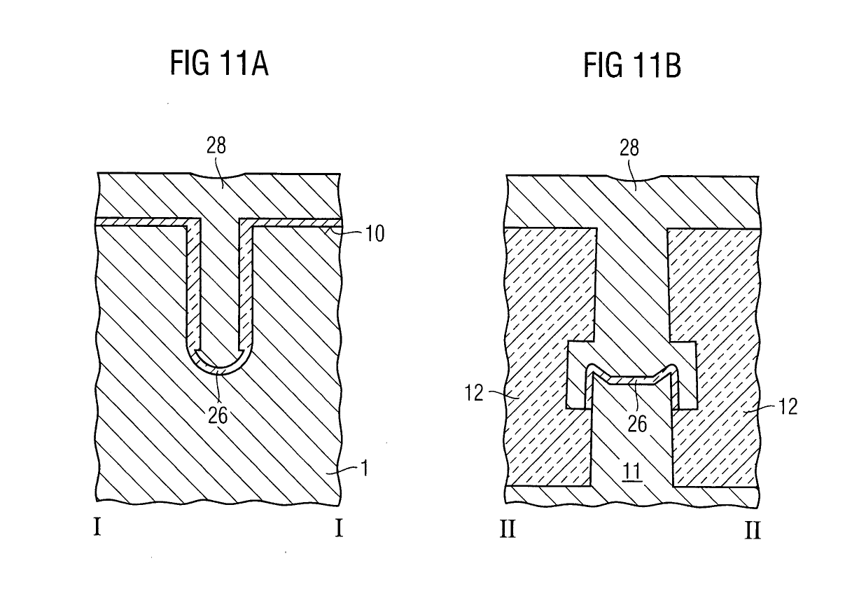

Thereafter, a gate conductive material 28 is provided in the gate groove so as to complete the memory cell transistor. FIGS. 11A and 11B show cross-sectional views of the structure after depositing the gate conductive material 28. By way of example, the gate conductive material 28 may be provided by performing a single deposition step. As a result, unwanted interfaces in the gate conductive material, which might be caused by performing separate deposition steps, can be avoided. In addition, the gate conductive material deposited in the array portion may as well act as a gate conductive material in the support portion. For example, the gate conductive material 28 may be amorphous silicon or polysilicon. Moreover, the amorphous silicon or polysilicon may be deposited undoped, followed by one or more ion implantation steps for providing the required dopant type. As an alternative, the amorphous silicon or polysilicon may be in-situ doped, followed by one or more ion implantation steps for providing the required counter-doping for one type (p- or n-type) of non-memory cell devices. Moreover, the gate conductive material 28 may as well comprise one or more metal layers.

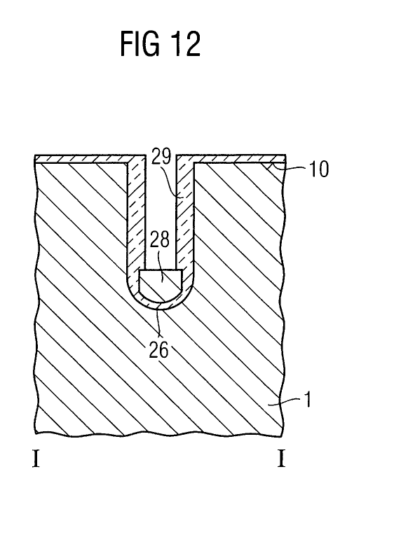

According to a further embodiment of the present invention, the gate conductive material 28 may be deposited by a two-step process. Accordingly, in a first step, a gate conductive material, for example polysilicon, is filled into the gate groove and recessed so that only the lower portion of the gate groove is filled with a polysilicon material. Thereafter, an inner spacer 29 is formed by a suitable method. For example, a silicon dioxide layer may be conformally deposited, followed by an anisotropic etching step so that the horizontal portions of the silicon dioxide layer are removed. FIG. 12 shows a cross-sectional view between I and I after this step of forming an inner spacer 29. As can be seen, the gate conductive material 28 fills the bottom portion of the gate groove, and the upper sidewall portion of the groove is covered with the spacer 29.

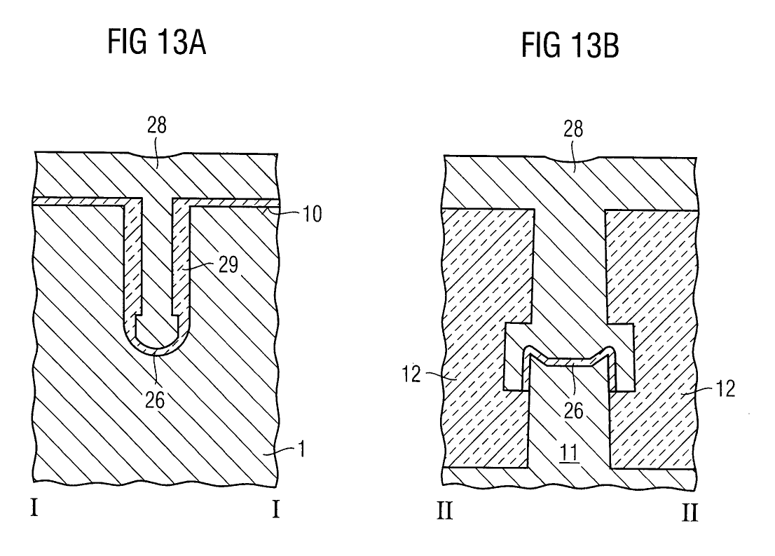

In the next step, the additional conductive material is deposited so as to completely fill the gate groove 20. The resulting structure is shown in FIGS. 13A and 13B, wherein FIG. 13A shows a cross-sectional view between I and I and FIG. 13B shows a cross-sectional view between II and II. As can be seen, now the entire surface of the substrate is covered with a gate conductive material 28.

Thereafter, starting from the structure shown in FIG. 11 or 13, the usual process steps for completing a memory cell are performed. For example, additional layers for constituting the gate stack such as a further conductive layer 451 and a cap layer 452 are deposited, followed by a patterning step of patterning single wordlines 45. Thereafter, first and second source/drain regions 41, 42 may be provided. Next, the usual planarizing and insulating layers are deposited, bitlines and corresponding bitline contacts are provided and the support or non-memory cell portion is completed in a conventional manner.

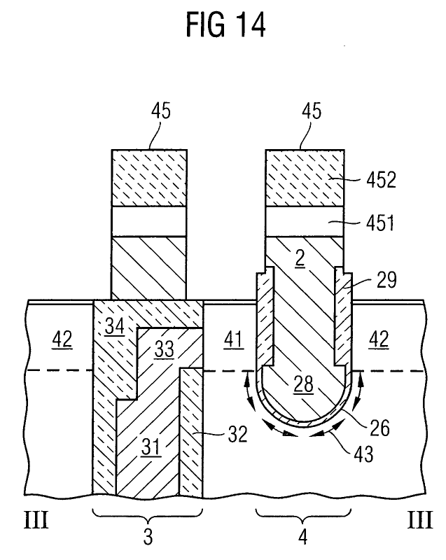

FIG. 14 shows a cross-sectional view of an exemplary memory cell incorporating the transistor which has been explained above with reference to FIGS. 1A and 1B respectively. On the left hand side of FIG. 14, the upper portion of a storage capacitor is shown. In the example shown, the storage electrode of such a storage capacitor is connected via the polysilicon filling 31 and the buried strap 33 with the first source/drain region 41 of the access transistor. On top of the polysilicon filling 31 and the buried strap 33, a trench top oxide 34 is provided. Although in the embodiment shown the storage capacitor is implemented as a trench capacitor, it is clearly to be understood that the invention may be arbitrarily practiced. For example, the transistor may as well be connected with a corresponding stacked capacitor which is at least partially formed above the substrate surface.

A transistor is formed by the first and second source/drain regions 41, 42, as well as by the gate electrode 2. The gate electrode 2 is insulated from the first and second source/drain regions 41, 42 by the gate insulating layer 26 and the spacer 29. Moreover, a channel 43 is formed between the first and second source/drain regions 41, 42. The conductive material 28 of the gate electrode is insulated from the channel 43 by the gate insulating layer 26. The conductive material 28 of the gate electrode 2 as well as the layers above 451, 452 are patterned so as to form single wordlines 45. When accessing the shown memory cell, the wordline 45 is set on appropriate voltage so that the transistor is switched on. Thereby an electrical charge stored in the storage electrode of the storage capacitor 3 is read out via the polysilicon filling 31, the first source/drain region 41, the channel 43 and the second source/drain region 42 to a corresponding bitline (not shown).

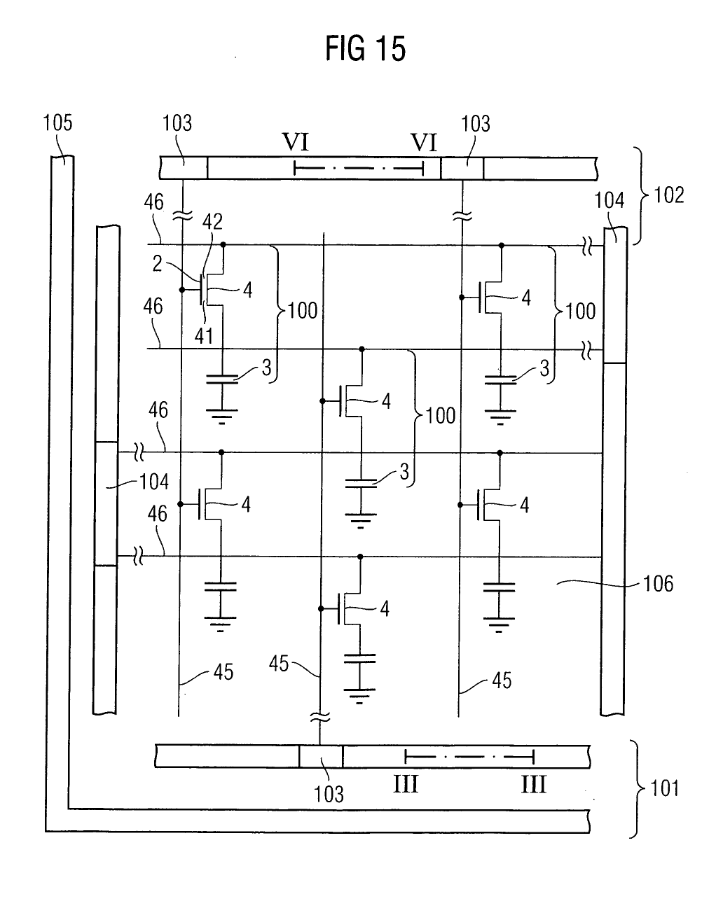

FIG. 15 shows a plan view of an exemplary memory device comprising transistors according to the present invention or transistors which can be manufactured by the method of the present invention. In the central portion of FIG. 15, the memory cell array 106 comprising memory cells 100 is shown. Each of the memory cells 100 comprises a storage capacitor 3 and an access transistor 4. The storage capacitor 3 comprises a storage electrode and a counter electrode, the storage electrode being connected with a corresponding one of the first source/drain regions 41 of the access transistors 4. The second source/drain region 42 of the access transistor 4 is connected with a corresponding bitline 46. The conductivity of the channel formed between the first and second source/drain regions 41, 42 is controlled by the gate electrode 2. The gate electrode 2 is addressed by a corresponding wordline 45. The access transistor 4 may be the transistor which has been described herein above with respect to FIGS. 1A and 1B. The storage capacitor 3 can for example be implemented as a trench capacitor or a stacked capacitor.

As is clearly to be understood, the specific layout of the memory cell array is arbitrary. In particular, the memory cells 100 can be arranged, for example, in a checkerboard pattern or any other suitable pattern. In the example shown in FIG. 15, the memory cell array is implemented as a folded bitline configuration. Nevertheless, as is clearly to be understood, the invention may as well be practised in a memory cell array in an open bit line configuration. The memory device of FIG. 15 further comprises a peripheral portion 101. Usually, the peripheral portion 101 comprises the core circuitry 102 including wordline drivers 103 for addressing the wordlines 45 and sense amplifiers 104 for sensing a signal transmitted by the bitlines 46. The core circuitry 102 usually comprises other devices and, for example, transistors, for controlling and addressing the individual memory cells 100. The peripheral portion 101 further comprises the support portion 105 which usually lies outside the core circuitry 102. The transistors of the peripheral portion can be arbitrary. For example, they can be implemented as conventional planar transistors. Nevertheless, they can as well be formed in the manner as is illustrated with reference to FIG. 1.

### LIST OF REFERENCE SYMBOLS

1 semiconductor substrate
10 substrate surface
11 active area
11a upper side
12 isolation trench
13 insulating material
14 Si3N4 layer
15 groove opening
15a oval opening
15b segment of stripe opening
17 recessed portion
18 groove flattening portion
2 gate electrode
2a upper gate electrode portion
2b lower gate electrode portion
20 gate groove
21 groove bottom portion
22 groove sidewall
221 lower sidewall portion
222 top sidewall portion
23 oxide liner
24 Si3N4 sidewall liner
25 Si tip
26 gate insulating layer
27 pocket
28 gate conductive material
29 spacer
3 storage capacitor
31 polysilicon filling
32 isolation collar
33 buried strap
34 trench top oxide
4 transistor
41 first source/drain region
42 second source/drain region
43 channel
43a upper channel portion
43b lower channel portion
44 plate-like portion
44a lower portion
45 wordline
451 conductive layer
452 cap layer
46 bitline
47 bottom side
48 upper side
100 memory cell
101 peripheral portion
102 core circuitry
103 wordline driver
104 sense amplifier
105 support portion
106 memory cell array

What is claimed is:

1. A method of forming a memory cell array, comprising:
a) defining the memory cell array to include a plurality of memory cells, each comprising a storage capacitor and a transistor;
b) defining isolation trenches adjacent to an active area; and
c) forming a gate electrode of the transistor by:
c1) selectively etching a gate groove in the active area with respect to an insulating material filling the isolation trenches, the gate groove including an upper sidewall portion, a lower sidewall portion and a bottom portion, the lower sidewall portion being adjacent to the bottom portion, the upper sidewall portion being disposed above the lower sidewall portion;
c2) etching the insulating material at a portion adjacent to a channel such that a portion of the channel is uncovered in the shape of a ridge comprising a top side and two lateral sides, the etching being performed by covering the upper sidewall portion of the gate groove with a cover layer such that a lower sidewall portion adjacent to the isolation trenches is left uncovered, and selectively etching the insulating material with respect to the material of the cover layer;
c3) providing a gate insulating material on the top side and the lateral sides; and
c4) providing a conducting material on the gate insulating layer such that the gate electrode is disposed along the top side and the two lateral sides of the channel.

2. The method of claim 1, wherein covering the upper sidewall portion with a cover layer comprises:
providing a sacrificial layer that covers the lower sidewall portion and the bottom portion of the gate groove;
providing the cover layer on the upper sidewall portion; and
removing the sacrificial layer from the lower sidewall portion.

3. The method of claim 2, wherein the sacrificial layer is made of the insulating material.

4. The method of claim 2, further comprising:
etching the bottom portion of the gate groove selectively with respect to the insulating material.

5. The method of claim 1, wherein covering the upper sidewall portion of the gate groove with a cover layer comprises providing the cover layer on the upper sidewall portion, the lower sidewall portion being provided by etching the bottom portion of the gate groove selectively with respect to the insulating material, the etching being performed after covering the upper sidewall portion of the gate groove with the cover layer.

6. The method of claim 2, wherein providing the cover layer comprises conformally depositing the cover layer and anisotropically etching the cover layer.

7. A method of forming a memory cell array, comprising:
providing a semiconductor substrate having a surface;
providing a plurality of isolation trenches in the semiconductor substrate, the isolation trenches extending in a first direction, thereby defining a plurality of active areas such that each active area is delimited by two isolation trenches along a second direction that is perpendicular to the first direction;
providing an insulating material in each of the isolation trenches;
providing a transistor in the active areas by providing first and a second source/drain regions, forming a channel disposed between the first and second source/drain regions, and providing a gate electrode for controlling an electrical current flow between the first and second source/drain regions; and
providing a plurality of storage capacitors;
wherein providing the gate electrode comprises:
etching a gate groove in an active area selectively with respect to the insulating material filling the isolation trenches, the gate groove including a sidewall and a bottom portion;
etching the insulating material at a portion adjacent to the channel such that a portion of the channel having the shape of a ridge comprising a top side and two lateral sides is uncovered, the etching including: covering the upper sidewall portion of the gate groove with a cover layer such that a lower sidewall portion adjacent to the isolation trenches is left uncovered, and selectively etching the insulating material with respect to the material of the cover layer;
providing a gate insulating layer on the top side and the two lateral sides; and
providing a conducting material on the gate insulating layer such that the gate electrode is disposed along the top side and the two lateral sides of the channel.

8. The method of claim 7, wherein covering the upper sidewall portion with a cover layer comprises:
providing a sacrificial layer that covers the lower sidewall portion and the bottom portion of the gate groove;
providing the cover layer on the upper sidewall portion; and
removing the sacrificial layer from the lower sidewall portion.

9. The method of claim 8, wherein the sacrificial layer is made of the insulating material.

10. The method of claim 8, further comprising:
etching the bottom portion of the gate groove selectively with respect to the insulating material.

11. The method of claim 7, wherein covering the upper sidewall portion of the gate groove with a cover layer comprises providing the cover layer on the upper sidewall portion, the lower sidewall portion being provided by etching the bottom portion of the gate groove selectively with respect to the insulating material, the etching being performed after covering the upper sidewall portion of the gate groove with the cover layer.

12. The method of claim 8, wherein providing the cover layer comprises conformally depositing the cover layer and anisotropically etching the cover layer.

13. A method of forming a transistor, comprising:
defining an active area by defining isolation trenches that are adjacent to the active area; and
forming a gate electrode by:
etching a gate groove in the active area selectively with respect to an insulating material filling the isolation trenches, the gate groove including an upper sidewall portion, a lower sidewall portion and a bottom portion, the lower sidewall portion being adjacent to the bottom portion of the gate groove, the upper sidewall portion being disposed above the lower sidewall portion;
etching the insulating material at a portion adjacent to a channel such that a portion of the channel having the shape of a ridge comprising a top side and two lateral sides is uncovered, the etching including: covering the upper sidewall portion with a cover layer such that a lower sidewall portion adjacent to the isolation trenches is uncovered, and selectively etching the insulating material with respect to the material of the cover layer;
providing a gate insulating material on the top side and the lateral sides; and
providing a conducting material on the gate insulating layer such that the gate electrode is disposed along the top side and the two lateral sides of the channel.

14. The method of claim 13, wherein covering the upper sidewall portion with a cover layer comprises:
providing a sacrificial layer that covers the lower sidewall portion and the bottom portion of the gate groove;
providing the cover layer on the upper sidewall portion; and
removing the sacrificial layer from the lower sidewall portion.

15. The method of claim 14, wherein the sacrificial layer is made of the insulating material.

16. The method of claim 14, further comprising:
etching the bottom portion of the gate groove selectively with respect to the insulating material.

17. The method of claim 13, wherein covering the upper sidewall portion of the gate groove with a cover layer comprises providing the cover layer on the upper sidewall portion, the lower sidewall portion being provided by etching the bottom portion of the gate groove selectively with respect to the insulating material, the etching being performed after covering the upper sidewall portion of the gate groove with the cover layer.

18. The method of claim 14, wherein providing the cover layer comprises conformally depositing the cover layer and anisotropically etching the cover layer.

19. A transistor, being at least partially formed in a semiconductor substrate, the transistor comprising:
first and second source/drain regions;
a channel formed between the first and the second source/drain regions; and
a gate electrode, disposed in a gate groove defined in the semiconductor substrate, that controls a conductivity of the channel;
wherein the channel has the shape of a ridge including a top side and two lateral sides and the gate electrode is adjacent to the top side and the two lateral sides; and
wherein the gate electrode comprises an upper portion and a lower portion, the lower portion of the gate electrode being adjacent to the top side of the channel, the upper portion being disposed above the lower portion, and wherein the upper portion has a smaller width than that in the lower portion in a cross-section that is perpendicular to a line connecting first and second source/drain regions.

20. The transistor of claim 19, wherein the upper portion of the gate electrode has sidewalls that are covered with a layer of an insulating material.

21. The transistor of claim 19, wherein the lower portion of the gate electrode further comprises two plate-like portions that are adjacent to the lateral sides of the channel.

22. A memory cell, comprising:
a charge-storing element; and
a transistor operable to access the charge-storing element, the transistor being at least partially formed in a semiconductor substrate having a surface and comprising:
first and second source/drain regions;
a channel between the first and the second source/drain regions; and
a gate electrode that controls a conductivity of the channel and disposed in a gate groove that is defined in the semiconductor substrate;
wherein:
the channel has the shape of a ridge including a top side and two lateral sides and the gate electrode is adjacent to the top side and the two lateral sides;
the gate electrode comprises an upper portion and a lower portion enclosing the ridge at three sides thereof; and
the gate electrode comprises means for reducing the width of the gate electrode in the lower portion with respect to the upper portion in a cross-section that is perpendicular to a line connecting the first and second source/drain regions.
